(19) United States
(12) Patent Application Publication
(10) Pub. No.: US 2021/0025401 A1
(43) Pub. Date: Jan. 28, 2021

(54) WIND DIRECTION CHANGING STRUCTURE OF FAN

(71) Applicant: PORTWELL INC., NEW TAIPEI CITY (TW)

(72) Inventor: YA-TZU SHIH, NEW TAIPEI CITY (TW)

(21) Appl. No.: 16/597,407

(22) Filed: Oct. 9, 2019

(30) Foreign Application Priority Data
Jul. 25, 2019 (TW) 108209711

(51) Int. Cl. F04D 19/00; G06F 1/20; F24F 7/013

(52) U.S. Cl. CPC F04D 19/005; F24F 7/013; G06F 1/206

(57) ABSTRACT

A wind direction changing structure includes a main body having a fan casing with an accommodation space, a fan connecting seat disposed on a side of the fan casing, a first socket and a second socket formed on the fan connecting seat and electrically connected to a fan control circuit, and at least one fan module having a fan plug. The fan plug of the fan module is plugged into the corresponding first socket, and after the fan module has rotated 180 degrees, the fan plug is plugged into the corresponding second socket, and the fan module is maintained to be rotated in the same direction. Therefore, the air blowing direction of the fan module can be set flexibly and the fan module can be plugged and unplugged directly, and components can be shared to lower the cost.

### FIELD OF INVENTION

The present disclosure relates to a fan module, in particular to a wind direction changing structure specially designed for a fan with a bidirectional operation to maintain a high operating efficiency of the fan.

### BACKGROUND OF INVENTION

In general, a computer system of an electronic product uses a cooling fan to dissipate heat. In the heat dissipating operation of the cooling fan, the cooling fan is rotated in a predetermined rotating direction to guide external air into the electronic product and dissipate the heat of a heat source to the outside. Since a large quantity of external air is guided into the electronic product, therefore dust may be accumulated in the electronic product easily, particularly in a special environment (such as a factory). At the beginning of starting the operation of the electronic product, the cooling fan is generally controlled to be rotated in a predetermined rotating direction for a period of time in order to guide the dust from the interior of the electronic product to the outside by the cooling fan, or after the cooling fan has been operated for a period of time, a reverse rotation is performed to remove the dust from the interior of the electronic product.

In the bidirectional rotation technology of the conventional fan module this sort as shown in FIG. 1, the cooling module 90 generally comprises a body 91 having an accommodation space 911, and a fan module 92 installed to a side of the body 91 adjacent to the accommodation space 911 and fixed onto a fan connecting seat 93 by a fastener 922, wherein a power supply device electrically coupled to the interior of the body 91 through the fan connecting seat 93, and the fan module 92 has a plurality of vanes 921. During operation, a control circuit installed in the body 91 is provided for controlling and performing a forward/reverse rotation of the fan module 92 to achieve the heat dissipation and dust removal effect of the body 91.

Although the aforementioned bidirectional rotation technology of the conventional fan module can achieve the forward/reverse rotation effect of the fan module 92, such technology still has the following drawbacks. For example, the fan module 92 guides airflow mainly by rotating the plurality of vanes 921, so that the design of the shape, radiant and curvature of the vanes 921 is fixed, and various different designs of the vanes are provided for a single rotating direction. In other words, the vanes have the optimal design of the shape, radiant and curvature for the single rotating direction, and thus the airflow guidance function of the vanes cannot be maximized when the vanes are used for rotations in an opposite direction. The airflow guidance efficiency may be reduced significantly during the rotation of the vanes, or vibrations and noises may even be produced. Obviously, such conventional fan bidirectional rotation design is not a very good solution.

In another conventional fan module bidirectional rotation technology as disclosed in R.O.C. Pat. No. TW 1556568 entitled “Forward/reverse rotation driving control circuit for a single-phase brushless DC fan motor”, the technologies similar to this patented technology also use a control circuit to control the forward/reverse rotation of a fan directly, and thus also have the same drawback of the bidirectional rotation of the vanes as described above and require further improvements. Obviously, it is a main subject for related manufactures to overcome the aforementioned drawback of the conventional fan module of the bidirectional operation.

In addition, the conventional fan extraction module does not come with a structural design for removing the original fan module and then turning the original fan module upside down and reinstalled, and thus the conventional fan extraction module has the drawback of the inconvenient removal and installation that requires a tool for the removal and installation.

In view of the aforementioned drawbacks of the prior art, the discloser of the present disclosure based on years of experience in the related industry to conduct research and experiment, and finally developed a wind direction changing structure with a high fan operation efficiency to overcome the drawbacks of the prior art.

### SUMMARY OF THE INVENTION

It is a primary objective of the present disclosure to provide a wind direction changing structure of a fan capable of providing bidirectional airflow operations while maintaining a single-direction airflow operation of the cooling fan module, protecting the vanes appropriately and featuring a quiet operation, so as to achieve the effects of assuring the quality and improving the service life of the product.

To achieve the aforementioned and other objectives, the present disclosure provides a wind direction changing structure, comprising: a main body, having a fan casing with an accommodation space formed therein, a fan connecting seat disposed on a side of the fan casing, and a first socket and a second socket formed on the fan connecting seat and electrically coupled to a fan forward rotation control circuit; at least one fan module, having a fan plug disposed at the bottom thereof; wherein the fan plug of the fan module is plugged into the corresponding first socket, and after the fan module has rotated 180 degrees, the fan plug is plugged into the corresponding second socket, and a fan of the fan module is maintained to be rotated in the same.

In this embodiment, the fan connecting seat comprises a conductive socket and socket panel.

In this embodiment, the conductive socket has an installation slot formed at the top thereof and communicated to an installation space inside the conductive socket.

In this embodiment, the socket panel installed on the top of the conductive socket, and the first socket and the second socket are formed at the corresponding installation slot of the socket panel, and the first socket has a first insert hole electrically coupled to a first power cable, and the second socket has a second insert hole electrically coupled to a second power cable, and both of the first power cable and the second power cable are electrically coupled to the fan forward rotation control circuit.

In this embodiment, at least one quick release assembly is installed between the fan connecting seat and the fan module and provided for fixing and assembling.

In this embodiment, the conductive socket has two quick release members disposed on both sides thereof respectively, and the socket panel has two quick release engagement slots formed on both sides thereof respectively, and the quick release member is passed and combined with the quick release engagement slot.

In this embodiment, the fan module has at least one quick release pin disposed on both sides of the bottom thereof, and the quick release pin has two quick insert slots.

In this embodiment, the fan plug is biased relative to a center line of the fan module.

In this embodiment, the fan module comprises a fan casing and the fan installed in the fan casing, and the fan comprises a plurality of vanes.

### BRIEF DESCRIPTION OF THE DRAWINGS

FIG. 1 is a schematic view of a conventional fan module;

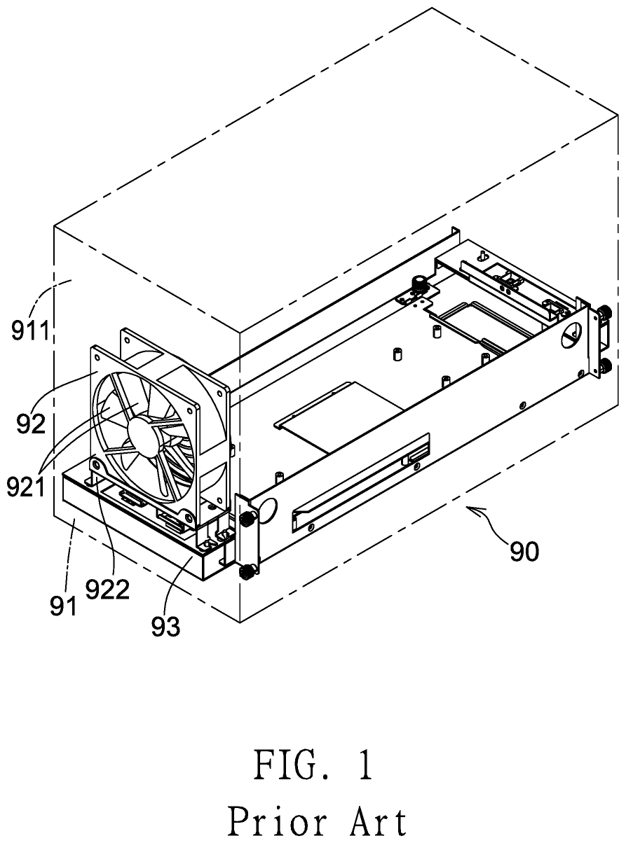

FIG. 2 is a first exploded view of the present disclosure;

FIG. 3 is a second exploded view of the present disclosure;

FIG. 4 is a first perspective view of the present disclosure; and

FIG. 5 is a second perspective view of the present disclosure

### DESCRIPTION OF THE PREFERRED EMBODIMENTS

To make it easier for our examiner to understand the technical content of the disclosure, we use preferred embodiments together with the attached drawings for the detailed description of the disclosure.

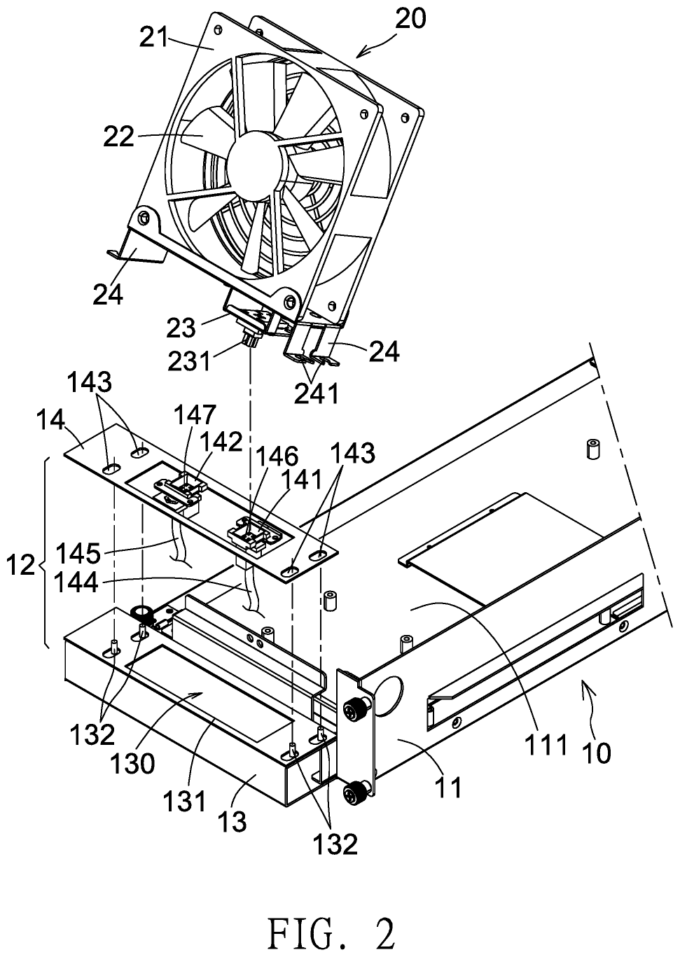

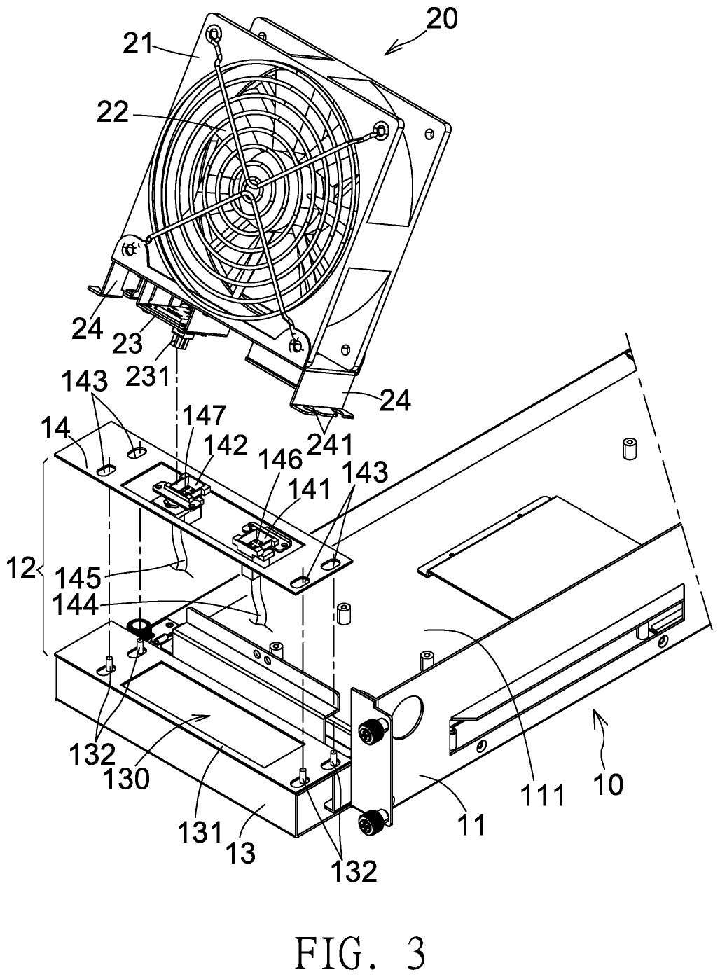

With reference to FIGS. 2 and 3 for a wind direction changing structure of a fan in accordance with the present disclosure, the wind direction changing structure comprises a main body 10 and a fan module 20, and the main body 10 has a fan casing 11, and the fan casing 11 has an accommodation space 111 formed therein and provided for installing related electric or other devices. A fan connecting seat 12 is installed on a side of the fan casing 11, and the fan connecting seat 12 comprises a conductive socket 13 and a socket panel 14, and the conductive socket 13 has comprises an installation slot 131 formed at the top thereof and communicated to an installation space 130 in the conductive socket 13, and both sides of the conductive socket 13 have two quick release members 132 respectively. The socket panel 14 is configured to be corresponsive to the top of the conductive socket 13, and the socket panel 14 has a first socket 141 and a second socket 142 formed at the corresponding installation slot 131, and the first socket 141 has a first insert hole 146 electrically coupled to the first power cable 144, and the second socket 142 has a second insert hole 147 electrically coupled to the second power cable 145, and the first power cable 144 and the second power cable 145 (or the first socket 141 and the second socket 142) are electrically coupled to a fan forward rotation control circuit. Of course, the fan forward rotation control circuit is electrically coupled to a power supply device (not shown in the figure). In addition, both sides of the socket panel 14 have two quick release engagement slots 143, and the quick release member 132 is passed and combined with the corresponding quick release engagement slot 143.

The fan module 20 comprises a fan casing 21 and a fan 22 installed in the fan casing 21, a fan plug 23 disposed on a side (such as the bottom) of the fan casing 21 (or the fan module 20), a conductive connecting post 231 protruding from the fan plug 23. In an embodiment, the fan plug 23 is biased relative to the center line of the fan casing 21 (or the fan module 20). In other words, the fan plug 23 is not disposed on the center line of the fan casing 21 (or the fan module 20), but this disclosure is not limited to such arrangement. The fan casing 21 (or fan module 20) has at least one quick release pin 24 disposed on both sides of the bottom thereof, and the quick release pin 24 has two quick insert slots 241. Wherein, the quick insert slot 241, the quick release engagement slot 143, and the quick release member 132 constitute a quick release assembly. The fan 22 comprises a plurality of vanes which comes with the design of general vanes and has the optimal design including the shape, radiant, and curvature for the airflow of single rotations, so as to provide a very good effect of guiding the rotating airflow.

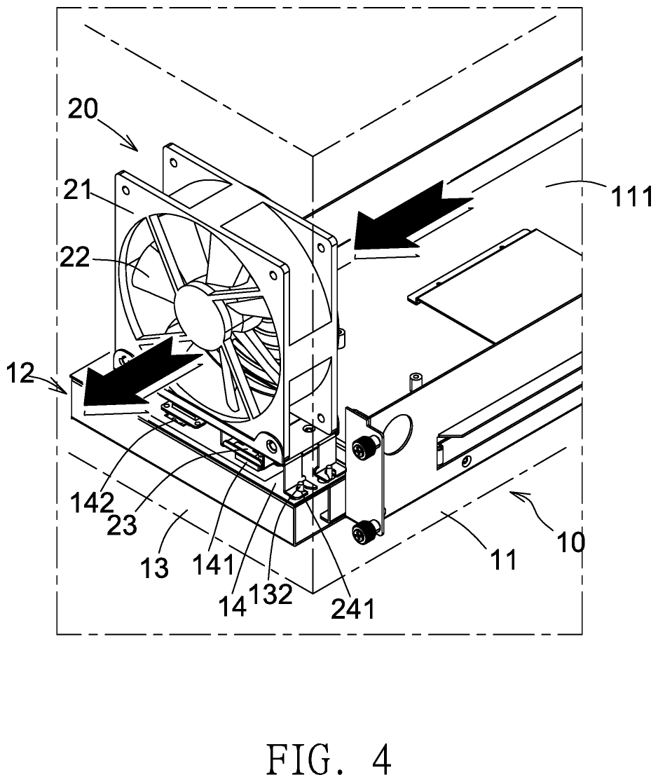

During the assembling process of the wind direction changing structure of the present disclosure as shown in FIGS. 2 and 4, the socket panel 14 is assembled to the conductive socket 13 to form the fan connecting seat 12, such that the fan connecting seat 12 (or the socket panel 14) has a first socket 141 and a second socket 142, and then the fan plug 23 of the fan casing 21 (or the fan module 20) is configured to be corresponsive to the first socket 141, and the conductive connecting post 231 is plugged into the first insert hole 146 to complete the electrical connection. Now, the quick release member 132 is also switched to be engaged with the quick insert slot 241 formed on both sides of the fan casing 21 (or the fan module 20) to achieve the stable assembled status of the fan module 20a as shown in FIG. 4. When the switch of the fan module 20 is turned on, the fan 22 is rotated and operated with the best efficiency according to the designed rotating direction of the vanes (such as the forward rotation) to discharge the air from the main body 10 (or the fan casing 11) to the outside, so as to perform the heat dissipation and dust removal operations.

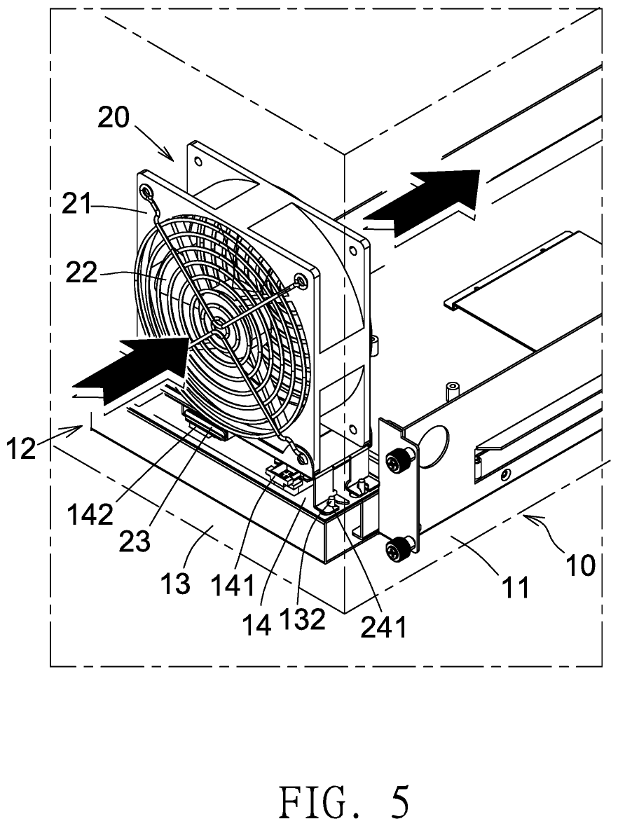

In the dust removal operation, it is necessary to discharge the dust or waste gas from the main body 10 (or the fan casing 11) to the outside. In FIGS. 3 and 5, if it is necessary to change the airflow direction of the fan module 20 relative to the main body 10 (or the fan casing 11), the wind direction changing structure of the present disclosure will switch the quick release member 132 to release the engagement from the quick insert slots 241 formed on both sides of the fan casing 21 (or the fan module 20), so that the fan casing 21 (or the fan module 20) can be lifted to separate the conductive connecting post 231 (or the fan plug 23) from the first insert hole 146 (or the first socket 141); and after the fan module 20 has rotated 180 degrees, the fan plug 23 at the bottom of the fan casing 21 (or the fan module 20) is aligned with the second socket 142, and the conductive connecting post 231 is plugged into the second insert hole 147 to complete the electrical connection. Now, the quick release member 132 is switched to be engaged with the quick insert slot 241 formed on both sides of the fan casing 21 (or the fan module 20) to complete the stable assembled status of the fan module 20 as shown in FIG. 5. When the fan module 20 is turned ON/OFF, the fan 22 performs a forward rotation. Since the fan module 20 has already rotated 180 and it is configured in an opposite direction, therefore the forward rotation of the fan 22 can guide external air into the main body 10 (or the fan casing 11) to perform the heat dissipation or dust removal operation. Regardless of the forward or reverse direction of the airflow of the fan module 20 for extracting or sucking air, the fan 22 maintains the same single-direction rotation (which is the forward rotation), so that the vanes of the fan 22 can comply with the corresponding operation of the original rotating design. The advantage of maintaining the vanes of the fan 22 to be rotated in a single rotating direction not just provides a high rotating efficiency of the fan 22 and maintains a long service life only, but also avoids vibrations adversely affecting the airflow guidance and prevents the production of annoying noises.

In the wind direction changing structure of the present disclosure, the air blowing direction of the fan module can be set flexibly and the fan module can be plugged and unplugged directly to reduce the assembling time and labor, and components can be shared to lower the cost.

While the present disclosure has been described by means of specific embodiments, numerous modifications and variations could be made thereto by those skilled in the art without departing from the scope and spirit of the invention set forth in the claims.

What is claimed is:

1. A wind direction changing structure, comprising:
a main body, having a fan casing with an accommodation space formed therein, a fan connecting seat disposed on a side of the fan casing, and a first socket and a second socket formed on the fan connecting seat and electrically coupled to a fan forward rotation control circuit;
at least one fan module, having a fan plug disposed at the bottom thereof;
wherein the fan plug of the fan module is plugged into the corresponding first socket, and after the fan module has rotated 180 degrees, the fan plug is plugged into the corresponding second socket, and a fan of the fan module is maintained to be rotated in the same.

2. The wind direction changing structure as claimed in claim 1, wherein the fan connecting seat comprises a conductive socket and socket panel.

3. The wind direction changing structure as claimed in claim 2, wherein the conductive socket has an installation slot formed at the top thereof and communicated to an installation space inside the conductive socket.

4. The wind direction changing structure as claimed in claim 3, wherein the socket panel installed on the top of the conductive socket, and the first socket and the second socket are formed at the corresponding installation slot of the socket panel, and the first socket has a first insert hole electrically coupled to a first power cable, and the second socket has a second insert hole electrically coupled to a second power cable, and both of the first power cable and the second power cable are electrically coupled to the fan forward rotation control circuit.

5. The wind direction changing structure as claimed in claim 1, further comprising at least one quick release assembly installed between the fan connecting seat and the fan module and provided for fixing and assembling.

6. The wind direction changing structure as claimed in claim 2, wherein the conductive socket has two quick release members disposed on both sides thereof respectively, and the socket panel has two quick release engagement slots formed on both sides thereof respectively, and the quick release member is passed and combined with the quick release engagement slot.

7. The wind direction changing structure as claimed in claim 6, wherein the fan module has at least one quick release pin disposed on both sides of the bottom thereof, and the quick release pin has two quick insert slots.

8. The wind direction changing structure as claimed in claim 1, wherein the fan plug is biased relative to a center line of the fan module.

9. The wind direction changing structure as claimed in claim 1, wherein the fan module comprises a fan casing and the fan installed in the fan casing, and the fan comprises a plurality of vanes.
